(19) United States
(12) Patent Application Publication
(10) Pub. No.: US 2010/0065320 A1
(43) Pub. Date: Mar. 18, 2010

(54) WIRING BOARD AND METHOD FOR MANUFACTURING THE SAME

(75) Inventor: Wataru Urano, Minato-ku (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION, Minato-ku, Tokyo (JP)

(21) Appl. No.: 12/517,286

(22) PCT Filed: Dec. 6, 2007
(86) PCT No.: PCT/JP2007/073602

§ 371 Date: Jun. 2, 2009

(30) Foreign Application Priority Data
Dec. 7, 2006 (JP) 2006-330627

(51) Int. Cl. H05K 1/11; H01K 3/10

(52) U.S. Cl. 174/261; 29/850

(57) ABSTRACT

Disclosed is a wiring board comprising a plurality of conductors (11) having a conductive member including first conductive material (1) and second conductive material (2), and insulating member (3) covering the conductive member. A plurality of conductors (11) are arranged lattice-like and are weaved like a woven cloth, and sections intersecting with each other are electrically connected.

### TECHNICAL FIELD

The present invention relates to a wiring board for performing an electrical connection and a method for manufacturing the same, and more particularly, a bendable wiring board and a method for manufacturing the same.

### BACKGROUND ART

With the recent development of technologies, electronic apparatuses have been made compact. Moreover, apparatuses which can be attached to the body of user, the so-called wearable apparatus, are being developed.

Such a wearable electronic apparatus requires a deformable wiring board. Generally, a flexible board has been known as a wiring board that is flexible.

In a process of manufacturing a flexible board, a wiring circuit is formed on a polyimide tape, using a process for manufacturing a general wiring board.

In addition, as one example of a flexible board related to the present invention, a flexible wiring board has been disclosed in Japanese Laid-Open Patent 1986-047686. In the construction of Japanese Laid-Open Patent 1986-047686, an etching resister is printed by silk screen printing on a woven-cloth-like flexible base material where synthetic fibers coated with a conductive metal are weaved lattice-like, and the conductive material is removed from the base material by an etching process, to thereby form a circuit pattern.

As another example of a bendable wiring board, a matrix circuit board has been disclosed in Japanese Patent Publications 2942398, 3246927 and 3471690. In the construction shown in Japanese Patent Publications 2942398, 3246927 and 3471690, the circuit board has a structure, where a portion of a metal conductor wire that constitutes an electrode is exposed as an electrode portion, on a woven-cloth-like flexible base material, where metal conductor wires covered with an insulating film are weaved lattice-like.

### DISCLOSURE

### Technical Problem

The above-described wiring boards that have a bendable structure, i.e., the wiring boards, which have flexibility, have a few problems.

First of all, the flexible board using the polyimide tape has the following problems.

As a first problem, since a plurality of processes such as boring, coating and circuit formation must be carried out in order in the manufacturing process, the number of the processes increases, and thus manufacturing requires a relatively long time.

As a second problem, in a case where an LSI (Large Scale Integration) circuit, having a plurality of terminal pins, is mounted on the wiring board, a multilayered structure is needed to wire the wiring therearound. However, the multilayered structure may degrade the flexibility of the flexible board.

Hereinafter, problems of the construction disclosed in Japanese Laid-Open Patent 1986-047686, will be described.

As a first problem, since a plurality of processes, including circuit formation, are necessary in the process of manufacturing the flexible board, the manufacturing time will increase.

As a second problem, silk screen printing is used in a circuit formation process, which is disadvantageous for achieving a high density circuit.

Hereinafter, a problem of the matrix circuit board disclosed in Japanese Patent Publications 2942398, 3246927 and 3471690 will be described.

As the problem of Japanese Patent Publications 2942398, 3246927 and 3471690, since the wiring constituting the circuit board and arranged lattice-like is composed of a metal conductor wire and an insulating material covering the metal conductor wire, in order to realize an electrical connection, the insulating material of the target connection portion on the wiring needs to be removed in advance to form an electrode. As a result, a plurality of processes and processing times are required to remove the insulating material.

An object of the present invention is to provide a wiring board, which can attain satisfactory flexibility, facilitate electrical circuit formation, and simplify the manufacturing process, and a method for manufacturing the same.

### Technical Solution

In order to accomplish the above object, a wiring board according to the present invention comprises a plurality of conductors including a conductive member having a first conductive material and a second conductive material, and an insulating member covering the conductive member, the plurality of conductors being arranged lattice-like and weaved like a woven cloth, sections intersecting with each other being electrically connected.

In the wiring board that has the above construction, according to the present invention, the first conductive material serves to attain not only the mechanical strength of the conductor but also electric conductivity, and the second conductive material, which is in contact with the first conductive material, serves to realize an electrical connection of the first conductive material by being in a molten state in e.g., because of the pressurizing heating process. In addition, the insulating member covering the conductive member composed of the first conductive material and the second conductive material serves to insulate the conductive member. Moreover, after the pressurized heated second conductive material is molten, when the first conductive material is bonded to a bonded object, such as a conductive member having another first conductive material pressed by the first conductive material, or such as an electrode of an electronic component, the insulating member removes a surface oxide film of the bonded object to which the first conductive material is to be bonded, to thereby perform an activating action that assists the process of fusion bonding of the second conductive material. Further, in the wiring board, any intersecting sections of the plurality of conductors arranged lattice-like are electrically connected, to easily form a desirable electrical circuit.

In addition, the second conductive material, provided in the wiring board according to the present invention, may cover a portion of the outer circumference of the first conductive material.

Moreover, in the conductor provided in the wiring board according to the present invention, the plurality of conductive members may be covered with the insulating member.

Further, in a wiring structure according to the present invention, the wiring board with the above construction may be stacked in a plural number and electrically connected, to thereby easily form a multilayered structure and attain satisfactory flexibility of the wiring board.

Also, according to the present invention, a method for manufacturing a wiring board where a plurality of conductors comprising a conductive member including a first conductive material and a second conductive material and an insulating member covering the conductive member are arranged lattice-like and weaved like a woven cloth, the method for manufacturing the wiring board, comprises a process of melting the second conductive material of the conductive member, and bonding the first conductive material to the first conductive material of another conductor intersecting therewith, by pressurizing and heating intersecting sections of the plurality of conductors.

### ADVANTAGEOUS EFFECTS

In accordance with the present invention, it is possible to attain satisfactory flexibility, facilitate electrical circuit formation, and simplify the manufacturing process of a wiring board.

### DESCRIPTION OF DRAWINGS

FIG. 1A is a schematic view for explaining a wiring board according to a first embodiment;

FIG. 1B is a schematic view for explaining the wiring board according to the first embodiment;

FIG. 1C is a schematic view for explaining the wiring board according to the first embodiment;

FIG. 2 is a schematic sectional view illustrating a part of a conductor according to a second embodiment;

FIG. 3 is a sectional view illustrating a conductor according to a third embodiment;

FIG. 4 is a sectional view illustrating a conductor according to a fourth embodiment;

FIG. 5 is a schematic sectional view illustrating a part of a conductor according to a fifth embodiment;

FIG. 6A is a schematic view for explaining a bonding process between conductors;

FIG. 6B is a schematic view for explaining the bonding process between the conductors;

FIG. 6C is a schematic view for explaining the bonding process between the conductors;

FIG. 7A is a schematic view for explaining a bonding process between a conductor and an electrode;

FIG. 7B is a schematic view for explaining the bonding process between the conductor and the electrode;

FIG. 7C is a schematic view for explaining the bonding process between the conductor and the electrode;

FIG. 8 is a schematic view for explaining an example of a process of collectively bonding a wiring board; and

FIG. 9 is a schematic view for explaining another example of the process of collectively bonding the wiring board.

### MODE FOR INVENTION

Hereinafter, embodiments of the present invention will be explained in detail with reference to the accompanying drawings.

### First Embodiment

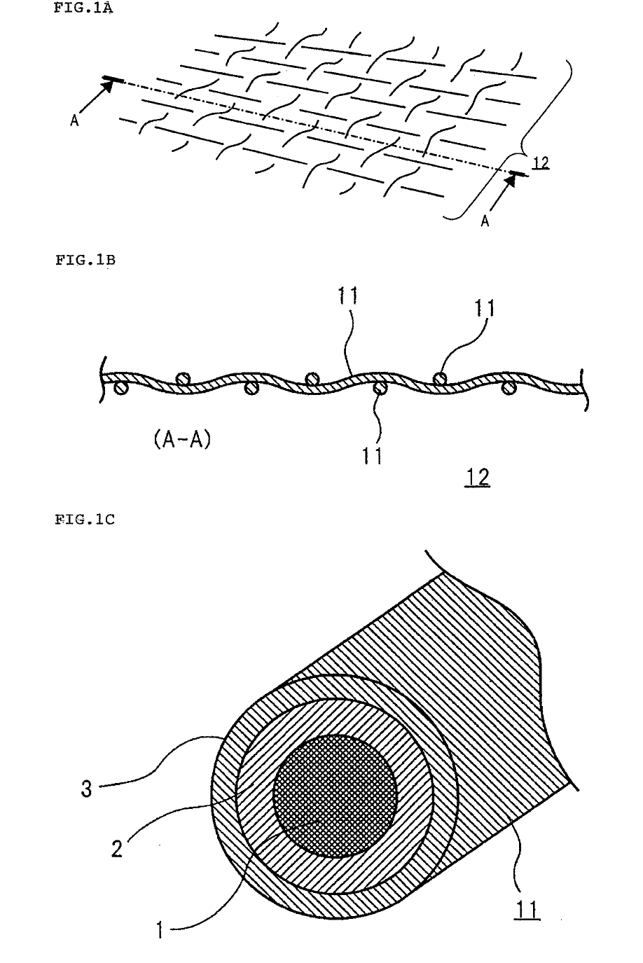

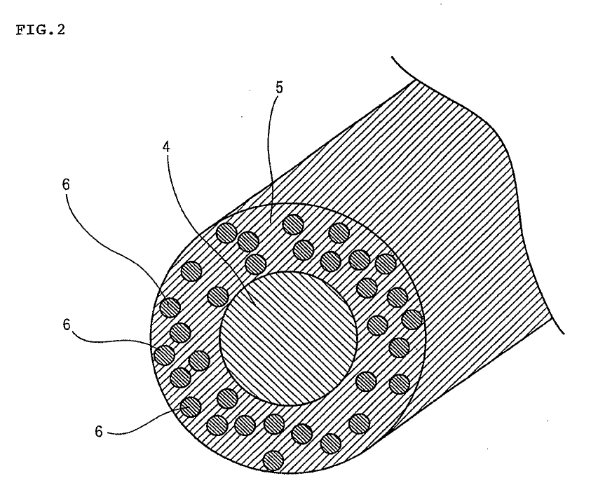

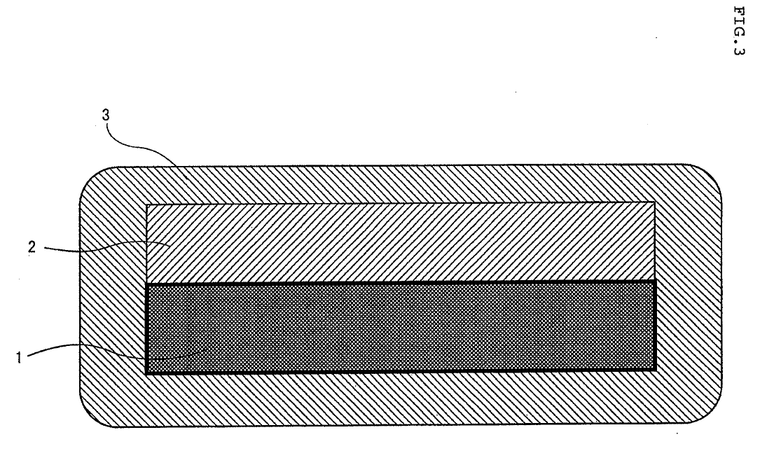

As illustrated in FIGS. 1A, 1B and 1C, in wiring board 12 of this embodiment, a plurality of conductors 11 including a conductive member having first conductive material 1 and second conductive material 2 and forming at least two-layered structure, and insulating member 3 covering the circumference of the conductive member are arranged lattice-like and weaved like a woven cloth. In addition, in wiring board 12, any intersecting sections of the plurality of conductors 11 are electrically connected, to thereby form an electrical circuit.

In conductor 11 constituting wiring board 12 of this embodiment, so as to attain mechanical strength and electric conductivity, a metal material, e.g., Cu, Ni and Al are suitable for a wire rod formed of first conductive material 1.

A material equivalent to a bonding wire, which can be relatively easily inserted, has a wire section diameter of Φ20 μm to Φ100 μm whose sizes satisfies the requirement for flexibility, is preferably used as first conductive material 1.

In linear conductor 11 constituting wiring board 12 of this embodiment, in order to realize an electrical connection by a pressurizing heating process, a soldered alloy material, e.g., SnAg and SnIn are suitable for second conductive material 2 which is in contact with first conductive material 1. Such a material is processed on the circumference of first conductive material 1 by e.g., plating, electro-deposition or molten alloy coating, or both materials are formed thin and bonded to each other, to thereby manufacture a linear conductive member of a two-layered structure.

Insulating member 3 covering the outermost circumference of the two-layered structure conductive member composed of first conductive material 1 and second conductive material 2 requires actions of insulating the conductive member, being molten below a melting point of second conductive material 2 in the pressurizing heating process, and being removed from the bonded section by a pressurization force. Accordingly, preferably used is a resin material that has heat resistance characteristics and that in a molten state in which the viscosity is relatively low. Added is a resin material such as B stage epoxy resin that has an activating action for removing an oxide film or thermoplastic polyimide resin that has an activating action for removing an oxide film. And, the resin material is extrusion-molded with two-layered structure conductor 11. The resin material dissolved by a solvent is covered by coating, etc., so that insulating member 3 is covered on the outer circumference of the conductive member.

Conductors 11 composed of the materials with the above-described functions are selected as warps and wefts and weaved, to thereby obtain aforementioned wiring board 12.

(Method for Manufacturing Wiring Board)

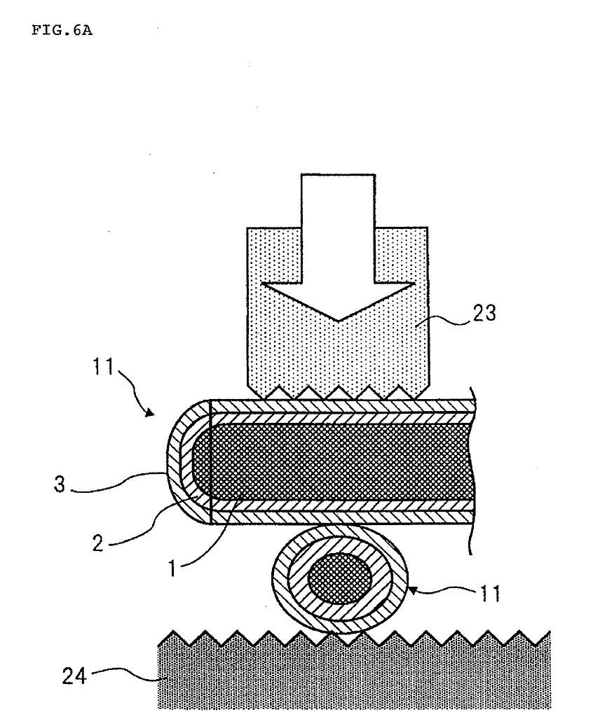

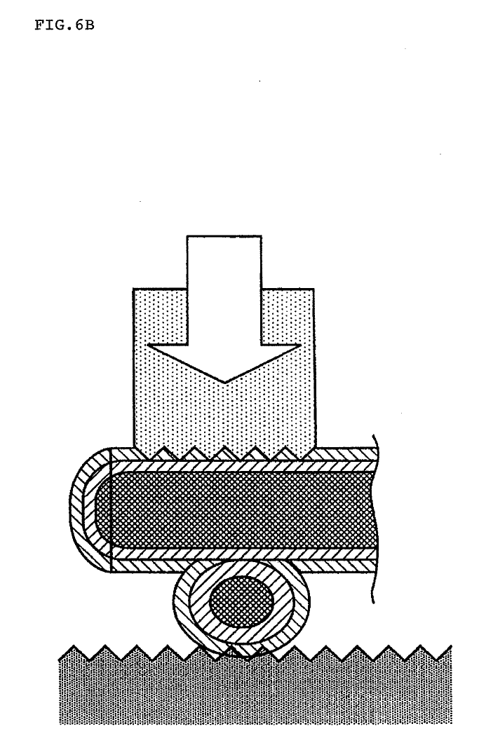

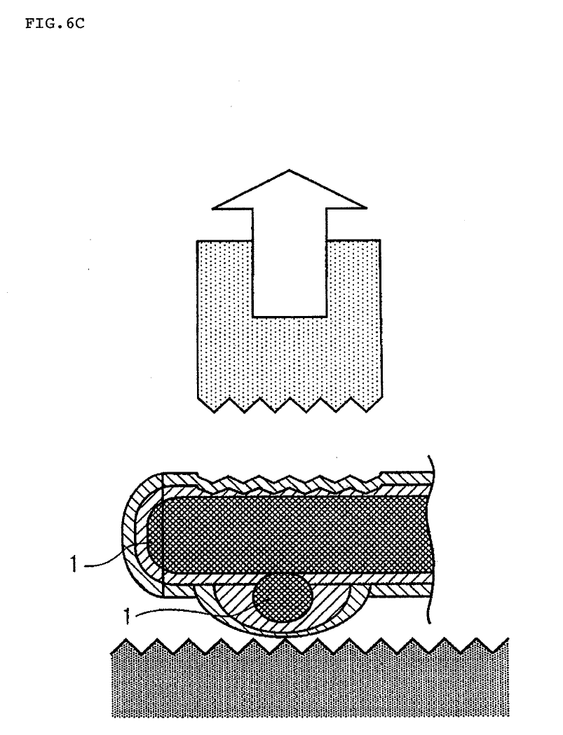

A process of electrically connecting plurality of conductors 11 arranged lattice-like to each other to form a circuit with respect to wiring board 12 of this embodiment will be described with reference to the attached drawings. FIG. 6 are schematic views for explaining a process of bonding intersecting sections of conductors 11 arranged lattice-like.

First of all, as illustrated in FIG. 6A, woven-cloth-like wiring board 12, where plurality of conductors 11 are arranged lattice-like and weaved, is prepared. Thereafter, intersecting sections of conductors 11 are pressurized and heated to be bonded to each other by a front end of pressing pin 23 heated at a higher temperature than a melting point of second conductive material 2 constituting conductor 11 by (+)20° C. to 30° C.

A temperature of conductor 11 rises due to the pressurizing heating process, and the covered layer positioned on the outermost side of conductor 11, i.e., insulating member 3 starts to be molten first. As shown in FIG. 6B, particularly in the sections where conductors 11 intersect and contact each other, molten insulating members 3 are crushed by a pressure that is caused by pressing conductors 11 to each other, and thus removed from between intersecting conductors 11. Thereafter, since insulating members 3 are removed from between conductors 11 in the intersecting sections of conductors 11, second conductive materials 2 intersecting with each other are put in contact.

While insulating member 3 is molten, second conductive material 2 is activated. When the temperature reaches melting point, second conductive materials 2 have become molten and are widely spread to enhance the bonding state in the bonded sections. As depicted in FIG. 6C, the pressurizing heating process is eliminated after a predetermined time that is needed to sufficiently bond the solder materials in the bonded sections, and the molten solder materials, i.e., insulating members 3 are hardened, to finish the bonding process.

As discussed earlier, in this embodiment, the intersecting sections of the plurality of conductors 11 arranged lattice-like are easily bonded by the pressurizing heating process, and electrically connected to form a target circuit.

Meanwhile, in the bonding process, in a case where a plurality of bonded portions, that cannot be electrically-standardized, exist on same conductor 11, the conductor, if necessary, can be cut by a cutting process using a cutting pliers, laser, etc. to form a plurality of wirings.

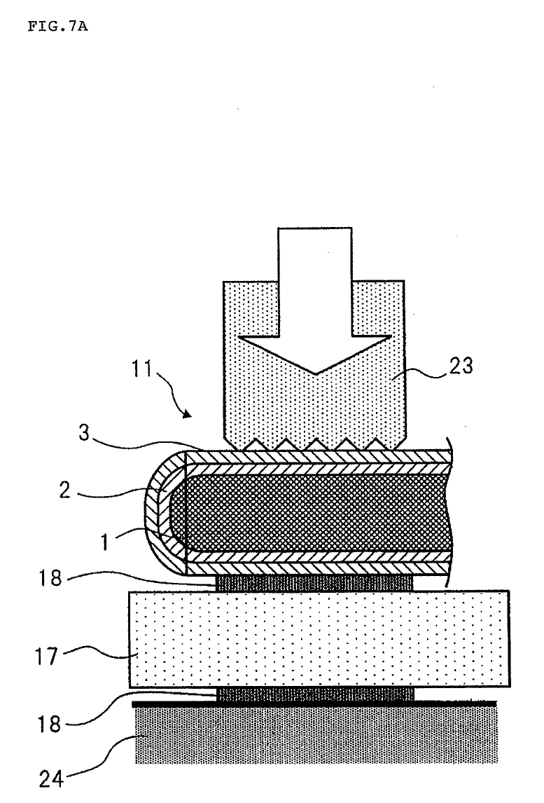

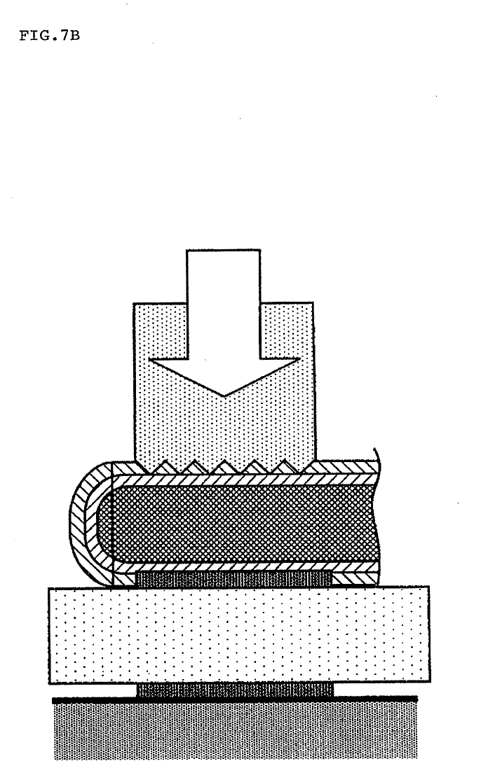

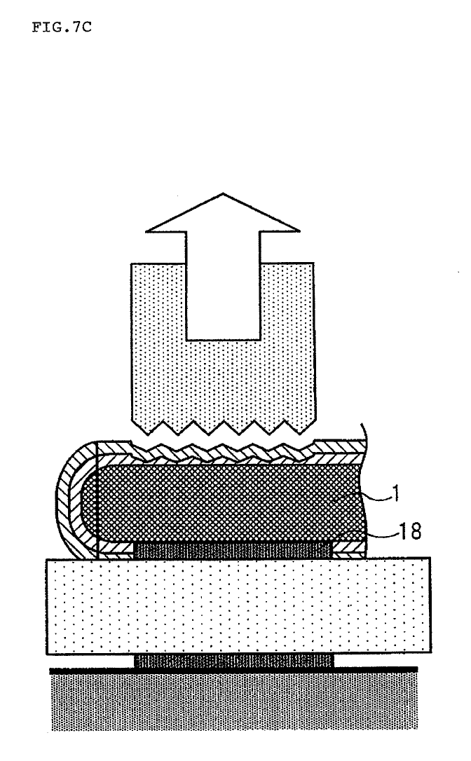

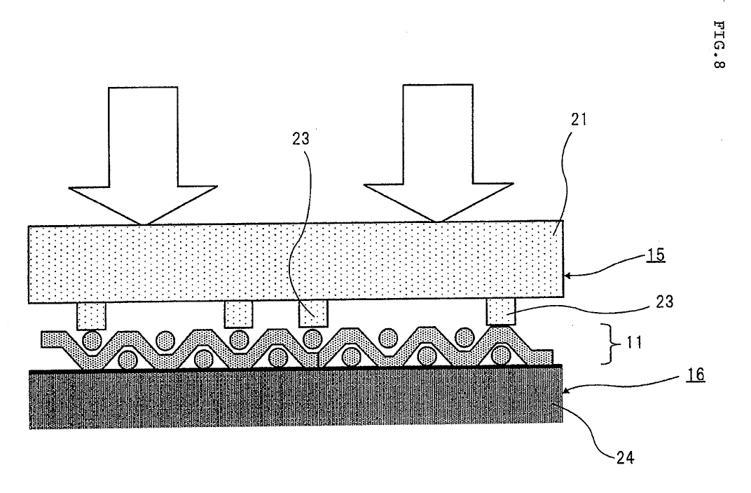

In addition, the present invention is not limited to bonding intersecting conductors 11. As illustrated in FIGS. 7A, 7B and 7C, for example, conductor 11 of wiring board 12 is pressurized and heated with respect to electrode 18 of the electronic component mounted on print board 17 by a front end of heated pressing pin 23, using a pressurizing heating process as in the above-described bonding process. Therefore, it is possible to bond conductor 11 to electrode 18 on the side of print board 17 through the medium of second conductive material 2.

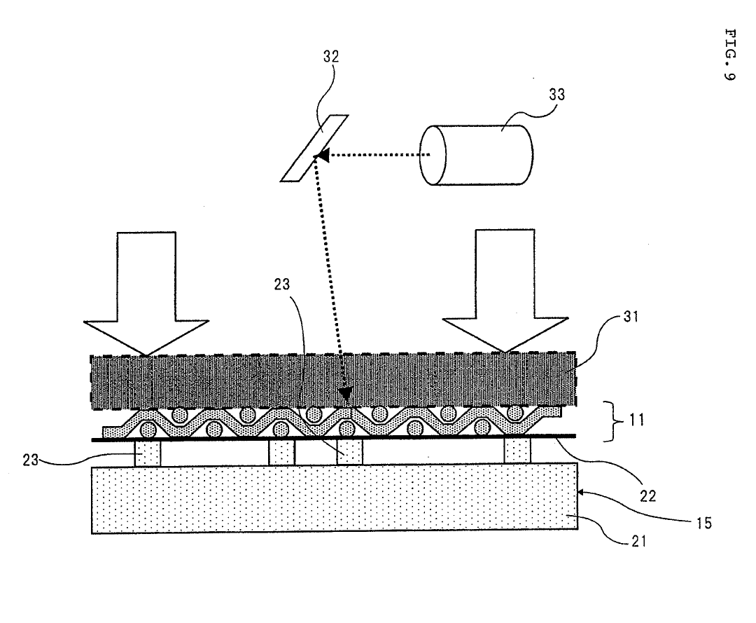

Moreover, as shown in FIG. 8, when a pressurizing heating process is individually carried out by front ends of pressing pins 23, it is possible to collectively bond a plurality of intersecting sections of respective conductors 11 of wiring board 12 by using jig 15 where a plurality of pressing pins 23 are arranged on heater 21, and on loading platform 16 where wiring board 12 is position-determined and loaded.

Further, in the same manner as the foregoing collective bonding method, as depicted in FIG. 9, in a state where sections to be pressurized and heated are pressurized by a jig including elastomer 22 and pressing pins 23, laser light from light source 33 is reflected by mirror 32 and irradiated through the medium of glass plate 31, so that it becomes possible to successively heat and bond the target sections and to fuse a plurality of sections of conductors 11 at the same time.

As described above, in wiring board 12 of this embodiment, since any intersecting sections of the plurality of conductors 11 arranged lattice-like are pressurized and heated, it is possible to easily bond conductors 11 within a relatively short time and to easily form a desirable electrical circuit.

Furthermore, in wiring board 12, intersecting conductors 11 are constrained merely in the bonded sections processed in the pressurizing heating process. Therefore, in a case where a plurality of wiring boards are constructed to be stacked, the bonded sections of the conductors are relatively narrowed particularly in the bent portions, to thereby embody a wiring board without degrading flexibility.

Still furthermore, since wiring board 12 is composed of the conductors arranged lattice-like, satisfactory permeability of gas or liquid can be attained on the front side and back side of the wiring board. Accordingly, the wiring board 12 prevents interference with the air permeability inside an electronic apparatus that uses wiring board 12.

### Second Embodiment

A second embodiment of a structural shape of conductors constituting a wiring board of the present invention will be explained. The wiring board of the second embodiment is different merely as regards the construction of the conductor from the wiring board of the first embodiment described above, and identical as regards the construction of the wiring board where conductors are arranged lattice-like and weaved to the wiring board of the first embodiment. Explanations of the same construction are omitted.

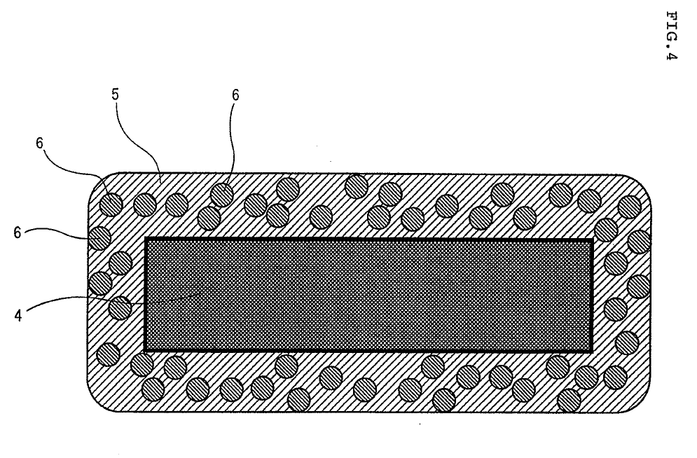

As illustrated in FIG. 2, conductor 11 constituting the wiring board of this embodiment includes a linear conductive member formed of first conductive material 4, and insulating member 5 covering first conductive material 4, where the plurality of particulate second conductive materials 6 are scattered in a base material. That is, particulate second conductive materials 6 are scattered in insulating member 5, and provided on the outer circumference of first conductive material 4 to be insulated from each other.

Same materials for first conductive material 1, second conductive material 2 and insulating member 3 in the first embodiment described above are used for first conductive material 4, particulate second conductive material 6 and insulating member 5 in the second embodiment.

A process of bonding intersecting sections of conductors 11 will be described with respect to the wiring board of the second embodiment.

The temperature of conductor 11 rises due to a pressurizing heating process, and insulating member 5 on the outermost circumference begins to reach a molten state first. Particularly, insulating members 5 molten in the intersecting sections of conductors 11 are crushed by a pressure that is caused by pressing conductors 11 against each other, and thus removed from between intersecting conductors 11. During this procedure, second conductive materials 6 contained in insulating member 5 start to be molten.

As surface oxide films or the like are removed by insulating member 5, second conductive materials 6 are surface-activated, and second conductive materials 6 and adjacent first conductive material 4 go into a molten state, furthermore, particles of second conductive materials 6 and particles of adjacent other second conductive materials 6 go into a molten state and the molten area becomes large. When first conductive materials 4 are bonded to each other, second conductive materials 6 are widely spread to firmly bond the bonded sections. The pressurizing heating process is eliminated after a predetermined time that is needed to bond the solder materials in the bonded sections, and the molten solder materials, i.e., insulating members 5, are hardened, to finish the bonding process.

As set forth above, in this embodiment, the intersecting sections of conductors 11 arranged lattice-like are easily bonded and electrically connected by the pressurizing heating process, to thereby form a desirable circuit.

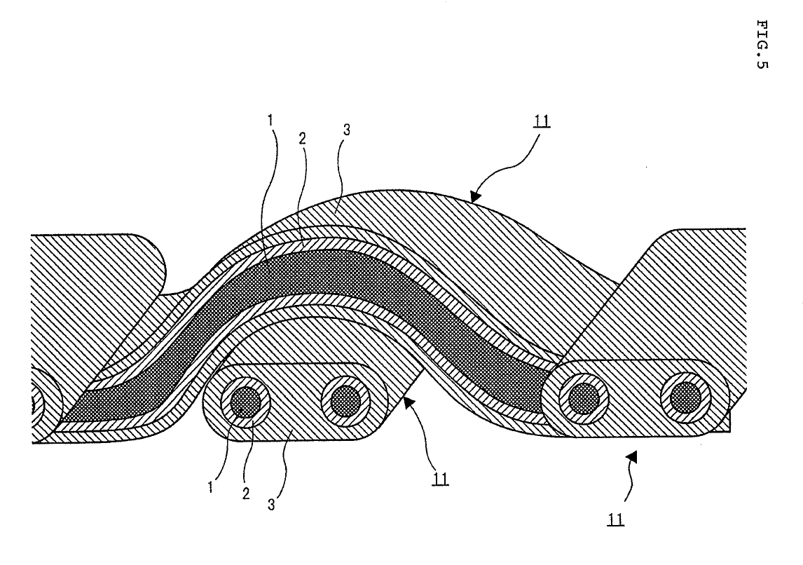

A third embodiment will be explained with reference to FIGS. 3 and 4.

A wiring board of the third embodiment includes a plurality of conductors arranged lattice-like and weaved as in the above-described embodiments. As illustrated in FIG. 3, a conductor provided in the wiring board of this embodiment has a two-layered structure where first conductive material 1 and second conductive material 2 are stacked, and has an almost rectangular section. The conductor has front side and back side because of its structure. The conductor is provided with a strip-like (ribbon-like) two-layered structure conductive member where first conductive material 1 is positioned on one side surface and second conductive material 2 is positioned on the other side surface, and is provided with insulating member 3 which covers the outer circumference of the two-layered structure conductive member, and is formed like a strip.

The strip-like conductor of the third embodiment has front side and back side because of its shape and structure. Therefore, in the wiring board of this embodiment, the entire strip-like conductors arranged lattice-like are weaved in the condition in which the front sides are matched with each other and the back sides are matched with each other.

In the wiring board of the third embodiment, although functions required for first conductive material 1, second conductive material 2 and insulating member 3 are identical to those of the first embodiment, since conductors 11 are formed strip-like, when a plurality of wiring boards are stacked to be multilayered, displacement of conductors 11 is prevented from occurring by an application of pressure, so that conductors 11 can be stably bonded in the pressurizing heating process. In addition, although the bonding process is identical to that of the first embodiment, in a case where the plurality of wiring boards are stacked as mentioned above, the wiring boards can be more easily stacked than in the first embodiment, by using the conductors of this embodiment.

Also, the same construction as the conductor of the second embodiment described above may be applied to a conductor having the rectangular section. In a fourth embodiment, strip-like conductors are constructed to be arranged lattice-like. As shown in FIG. 4, the strip-like conductor of the fourth embodiment includes a strip-like conductive member formed of first conductive material 4, and insulating member 5 covering first conductive material 4, where plurality of particulate second conductive materials 6 are scattered in a base material.

The fifth embodiment will be explained with reference to FIG. 5. As depicted in FIG. 5, a conductor provided in a wiring board of the fifth embodiment uses a linear conductive member constituting the wiring boards of the first embodiment and the third embodiment and having first conductive material 1 and second conductive material 2. In a state where every two conductive members maintain a regular interval, the two conductive members are covered with insulating member 3.

A process of bonding the conductors in the wiring board of the fifth embodiment is identical to the bonding process of the first embodiment. However, according to this embodiment, since every two conductive members maintain a regular interval, the number of conductive members that are used per unit area is reduced. Moreover, in a state where the first conductive material and the second conductive material are cut, insulating member 3 existing between the conductive members is still connected therebetween, so that the conductors can maintain a satisfactory lattice-like weaved shape.

In the meantime, the conductor provided in the wiring board of the foregoing embodiment adopts a construction of covering the entire region of the outer circumference of the first conductive material with the second conductive material. However, a portion of the first conductive material may be covered with the second conductive material.

Moreover, according to a method for manufacturing a wiring board of the present invention, a plurality of intersecting sections of conductors can be collectively bonded to easily form a circuit of the wiring board. Further, a wiring board of the present invention is applicable to a wiring board structure where only certain bent portions have flexibility.

While the present invention has been described in connection with the preferred embodiments, the present invention is not limited thereto. Therefore, it will be understood by those skilled in the art that various modifications and changes can be made to the construction or details of the present invention within the scope of the present invention.

This application claims priority based on Japanese Patent Application No. 2006-330627 filed on Dec. 7, 2006, the entire contents of which are incorporated herein by reference.

1. A wiring board, comprising a plurality of conductors having a conductive member including a first conductive material and a second conductive material, and an insulating member covering the conductive member, wherein
the plurality of conductors being arranged lattice-like and weaved like a woven cloth, sections intersecting with each other being electrically connected.

2. The wiring board according to claim 1, wherein
the first conductive material and the second conductive material of the conductive member constitute a two-layered structure.

3. The wiring board according to claim 1, wherein
the first and second conductive materials are formed of a metal material, the second conductive material covers the linear first conductive material, and the insulating member is formed of a resin material having a function of activating an oxidized surface of a bonded object, to which the first conductive material is to be bonded, when the second conductive material is molten.

4. The wiring board according to claim 1, wherein
the first and second conductive materials are formed of a metal material, the second conductive material is formed into a plurality of particles, and scattered in the insulating member covering the linear first conductive material, and the insulating member is formed of a resin material having a action of activating an oxidized surface of a bonded object, which the first conductive material is to be bonded, when the second conductive material is molten.

5. The wiring board according to claim 2, wherein
the conductive member is formed into a strip by stacking the first conductive material and the second conductive material, and
the plurality of conductors are weaved, matching the directions of the first conductive materials and the second conductive materials of the conductive members.

6. The wiring board according to claim 1, wherein
the second conductive material covers a portion of the outer circumference of the first conductive material.

7. The wiring board according to claim 3, wherein
the conductor is constructed of the plurality of conductive members, which are covered with the insulating member.

8. The wiring board according to claim 1, wherein
in the intersecting sections of the plurality of conductors, the second conductive materials are molten, so that the first conductive materials intersecting with each other are bonded.

9. A wiring board structure, wherein
the wiring board according to claim 1, which is stacked in a plural number and which is electrically connected.

10. A method for manufacturing a wiring board where a plurality of conductors, having a conductive member including a first conductive material and a second conductive material and an insulating member covering the conductive member, are arranged lattice-like and weaved like a woven cloth,
the method for manufacturing the wiring board, comprising a process of melting the second conductive material of the conductive member, and bonding the first conductive material to the first conductive material of another conductor intersecting therewith, by pressurizing and heating intersecting sections of the plurality of conductors.

11. The method according to claim 10, wherein
the conductive member, is constructed of a two-layered structure in which the first conductive material and the second conductive material are stacked.
